(19) United States
(12) Patent Application Publication
(10) Pub. No.: US 2008/0179722 A1
(43) Pub. Date: Jul. 31, 2008

(54) ELECTRONIC PACKAGE STRUCTURE

(75) Inventors: Da-Jung Chen, Taoyuan County (TW); Chung-Shiun Fang, Tainan County (TW); Bau-Ru Lu, Changhua County (TW); Yi-Cheng Lin, Pingtung County (TW); Chau-Chun Wen, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: CYNTEC CO., LTD., Hsinchu (TW)

(21) Appl. No.: 11/930,183

(22) Filed: Oct. 31, 2007

Related U.S. Application Data
(63) Continuation-in-part of application No. 11/684,645, filed on Mar. 12, 2007.

(30) Foreign Application Priority Data
Jan. 31, 2007 (TW) 96103493

(51) Int. Cl. H01L 23/495

(52) U.S. Cl. 257/666; 257/E23.031

(57) ABSTRACT

An electronic package structure including a first carrier, at least one first electronic element, at least one second electronic element, and an encapsulant is provided. The first carrier has a first carrying surface and a second carrying surface opposite to the first carrying surface. The first electronic element is disposed on the first carrying surface and electrically connected to the first carrier. The second electronic element is disposed on the second carrying surface and electrically connected to the first carrier. The encapsulant at least covers the first electronic element, the second electronic element, and a part of the first carrier. The space utilization rate of the first carrier of the electronic package structure is higher.

### CROSS-REFERENCE TO RELATED APPLICATION

This application is a continuation-in-part of a prior application Ser. No. 11/684,645, filed on Mar. 12, 2007, which claims the priority benefit of Taiwan application serial no. 96103493, filed on Jan. 31, 2007. The entity of each of the above-mentioned patent applications is incorporated by reference herein and made a part of specification.

### BACKGROUND OF THE INVENTION

1. Field of the Invention

The present invention relates to a package structure. More particularly, the present invention relates to an electronic package structure.

2. Description of Related Art

Electronic package structures are fabricated through very complicated package processes. The electronic package structures have different electrical performances and heat dissipation capacities. Thus, a designer may select an electronic package structure having suitable electrical performance and heat dissipation capacity according to his/her own requirement.

FIG. 1 is a schematic view of a conventional electronic package structure. Referring to FIG. 1, the conventional electronic package structure 100 includes a printed circuit board (PCB) 110 and a plurality of electronic elements 120. The electronic elements 120 are disposed on a surface 112 of the PCB 110 and electrically connected to the PCB 110. The PCB 110 has a plurality of pins 116 extended from another surface 114 of the PCB 110. The PCB 110 can be electrically connected to a next-level electronic apparatus (for example, a mainboard, which is not shown) via these pins 116. However, since all the electronic elements 120 of the electronic package structure 100 are small first-level packages and the surface 112 of the PCB 110 has a certain area for circuit layout, the volume of the electronic package structure 100 is very large. Besides, the fabricating cost of the electronic package structure 100 is very high for these electronic elements 120 have to be pre-formed through a first-level package process. Moreover, the electronic package structure 100 has to be inserted into the next-level electronic apparatus manually, thus, the electronic package structure 100 and the next-level electronic apparatus cannot be assembled automatically.

Another conventional electronic package structure is provided for resolving foregoing problems. FIG. 2 is a schematic view of another conventional electronic package structure. Referring to FIG. 2, the conventional electronic package structure 200 includes a package substrate 210 and a plurality of electronic elements 220. The electronic elements 220 are disposed on a surface 212 of the package substrate 210 and electrically connected to the package substrate 210 through wire bonding technology or surface mount technology. In addition, the electronic package structure 200 can be electrically connected to a next-level electronic apparatus (for example, a mainboard, which is not shown) via solder paste or a plurality of solder balls (not shown).

Compared to the electronic package structure 100, the electronic package structure 200 has following advantages, such as higher element disposition density, smaller volume, simpler fabrication process, lower cost, and the capability of being assembled into a next-level electronic apparatus automatically. However, heat produced during the operation of the electronic package structure 200 can only be conducted to the leads of the next-level electronic apparatus via the conductive vias 214 in the package substrate 210. Accordingly, the heat dissipation capacity of the electronic package structure 200 is unsatisfactory.

Moreover, the electronic elements 120 of the conventional electronic package structure 100 are all disposed on the surface 112 of the PCB 110, and the electronic elements 220 of the conventional electronic package structure 200 are all disposed on the surface 212 of the package substrate 210. Therefore, in the conventional electronic package structures 100 and 200, the space utilization rate of the PCB 110 and the package substrate 210 is low, and the volumes of the conventional electronic package structures 100 and 200 are large.

### SUMMARY OF THE INVENTION

The present invention is directed to an electronic package structure, having a higher utilization rate of interior space.

The present invention provides an electronic package structure, including a first carrier, at least one first electronic element, at least one second electronic element, and an encapsulant. The first carrier has a first carrying surface and a second carrying surface opposite to the first carrying surface. The first electronic element is disposed on the first carrying surface and electrically connected to the first carrier. The second electronic element is disposed on the second carrying surface and electrically connected to the first carrier. The encapsulant at least covers the first electronic element, the second electronic element, and a part of the first carrier.

In an embodiment of the present invention, the volume of the second electronic element can be larger than that of the first electronic element.

In an embodiment of the present invention, the number of the first electronic element(s) can be plural. Moreover, one of the first electronic elements can be a control element, another one of the first electronic elements can be a power element, and the second electronic element can be an energy-storage element. Moreover, one of the first electronic elements can be a control element, another one of the first electronic elements can be an energy-storage element, and the second electronic element can be a power element.

In an embodiment of the present invention, the number of the second electronic element(s) can be plural. Moreover, the first electronic element can be a control element, one of the second electronic elements can be an energy-storage element, and another one of the second electronic elements can be a power element.

In an embodiment of the present invention, the electronic package structure further includes at least one third electronic element disposed on a side surface of the first carrier, and the side surface connects the first carrying surface and the second carrying surface. Moreover, the third electronic element can be an energy-storage element, the first electronic element can be a control element, and the second electronic element can be a power element.

In an embodiment of the present invention, the first carrier can be a leadframe.

In an embodiment of the present invention, the electronic package structure further includes a second carrier disposed on the first carrying surface and electrically connected to the first carrier. Moreover, the first electronic element is disposed on the second carrier and electrically connected to the second carrier. Moreover, the electronic package structure further includes an underfill disposed between the second carrier and the first electronic element. Further, the number of the first electronic element(s) can be plural. A part of the first electronic elements are disposed on the second carrier and electrically connected to the second carrier, and the rest part of the first electronic elements are disposed on the first carrying surface and electrically connected to the first carrier. In addition, the second carrier can be a wiring board.

In an embodiment of the present invention, the first electronic element can be directly disposed on the first carrying surface, and the second electronic element can be directly disposed on the second carrying surface.

As described above, since the second electronic element is disposed on the second carrying surface of the first carrier, and the first electronic element is disposed on the first carrying surface of the first carrier, the carrying space of the first carrier can be fully utilized. Therefore, the electronic elements in the electronic package structure of the present invention can be disposed in higher density.

In order to make the aforementioned features and advantages of the present invention comprehensible, preferred embodiments accompanied with figures are described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic view of a conventional electronic package structure.

FIG. 2 is a schematic view of another conventional electronic package structure.

FIG. 3A is a schematic cross-sectional view of an electronic package structure according to a first embodiment of the present invention.

FIG. 3B is a schematic view of possible extension modes of leads of a leadframe according to the first embodiment of the present invention.

FIG. 3C is a schematic cross-sectional view of another electronic package structure according to the first embodiment of the present invention.

FIG. 4 is a schematic cross-sectional view of an electronic package structure according to a second embodiment of the present invention.

FIG. 5 is a schematic cross-sectional view of an electronic package structure according to a third embodiment of the present invention.

FIG. 6 is a schematic cross-sectional view of an electronic package structure according to a fourth embodiment of the present invention.

FIG. 7 is a schematic cross-sectional view of an electronic package structure according to a fifth embodiment of the present invention.

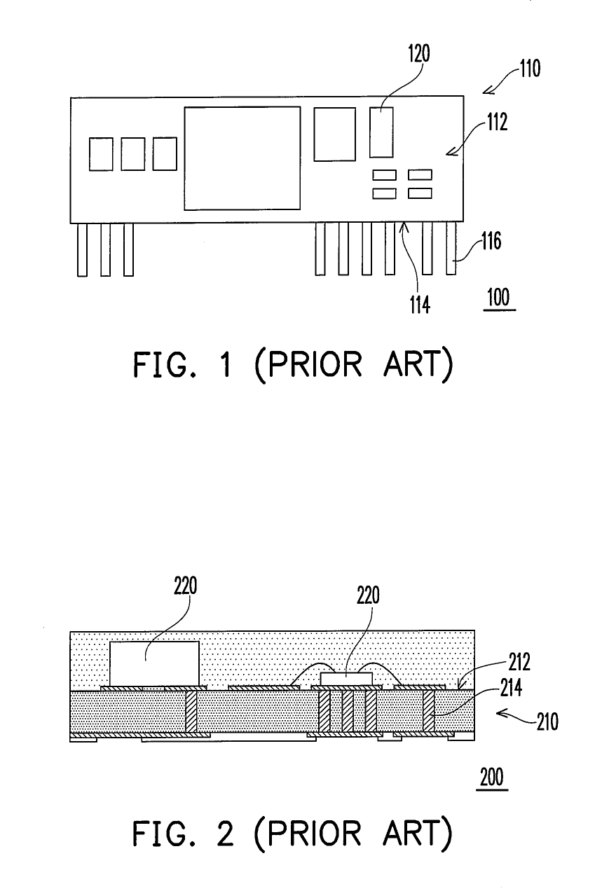

### DESCRIPTION OF EMBODIMENTS

### The First Embodiment

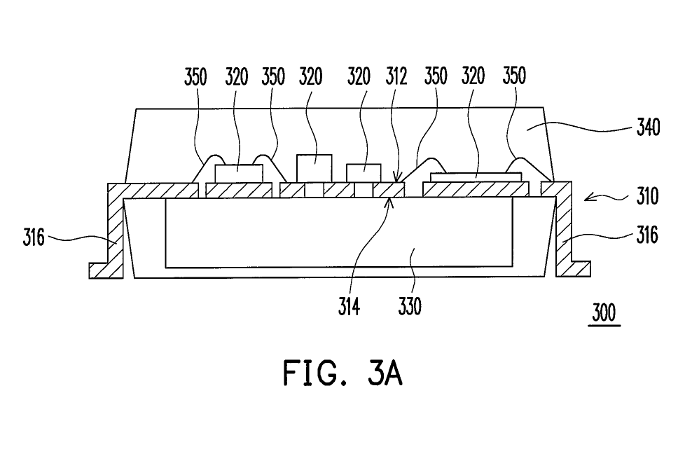

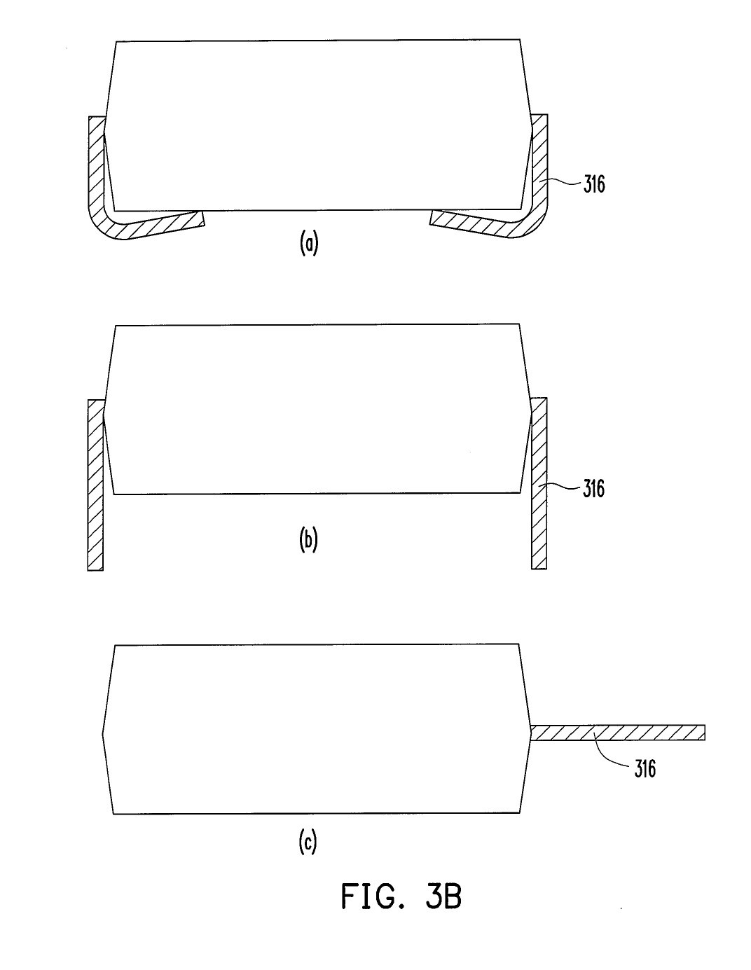

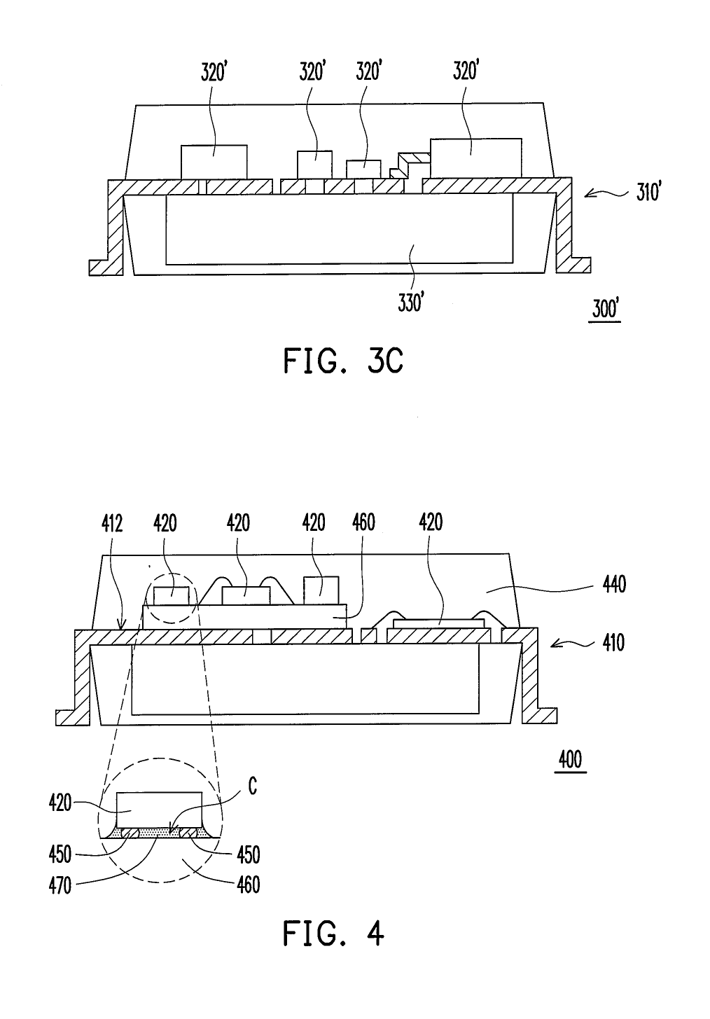

FIG. 3A is a schematic cross-sectional view of an electronic package structure according to a first embodiment of the present invention. Referring to FIG. 3A, the electronic package structure 300 of the first embodiment includes a first carrier 310, at least one first electronic element 320, at least one second electronic element 330, and an encapsulant 340. The first carrier 310 has a first carrying surface 312 and a second carrying surface 314 opposite to the first carrying surface 312. The first electronic elements 320 are disposed on the first carrying surface 312 and electrically connected to the first carrier 310. The second electronic element 330 is disposed on the second carrying surface 314 and electrically connected to the first carrier 310.

In this embodiment, four first electronic elements 320 and one second electronic element 330 are schematically depicted in FIG. 3A, the volume of the second electronic element 330 can be larger than that of the first electronic elements 320, and the first carrier 310, for example, is a leadframe made of a metal material. In this embodiment, the first electronic elements 320 can be directly disposed on the first carrying surface 312, and the second electronic element 330 can be directly disposed on the second carrying surface 314.

As the second electronic element 330 can be designed to be disposed on the second carrying surface 314 of the first carrier 310, and the first electronic elements 320 can be designed to be disposed on the first carrying surface 312 of the first carrier 310, the carrying space of the first carrier 310 can be fully utilized. Therefore, the electronic elements 320 and 330 in the electronic package structure 300 can be disposed in higher density.

In the first embodiment, the second electronic element 330 can be an energy-storage element for storing electric energy. In detail, the second electronic element 330 can be a choke coil, which can be regarded as an inductive element with high inductance and large volume. In addition, the number of the first electronic elements 320 can be plural, and each of the first electronic elements 320 can be a logic control element, a driving element, or a passive element. The passive element, for example, is a capacitor, an inductor with low inductance, or a resistor. Each of the first electronic elements 320 can also be a power element including a metal-oxide-semiconductor field effect transistor (MOSFET), an insulated gate bipolar transistor (IGBT), or a diode. In addition, the electronic package structure 300 of the first embodiment is normally applied in voltage regulator modules, network adapters, graphics processing units, DC/DC converters, or point-of-load (POL) converters.

The encapsulant 340 of the first embodiment at least covers the first electronic elements 320, the second electronic element 330, and a part of the first carrier 310, so as to protect the electronic elements 320 and 330. Moreover, at least one lead 316 (two leads 316 are schematically depicted in FIG. 3A) of the first carrier 310 (e.g., a leadframe) extends outside the encapsulant 340, so as to being electrically connected to a next-level electronic apparatus, e.g., a motherboard (not shown). In this embodiment, the electronic package structure 300 can be a surface mount device (SMD). For example, the SMD can be made through the QFP package (as shown in FIG. 3A) technology or PLCC package (as shown in FIG. 3B(a)) technology, and the leads 316 can be electrically connected to the next-level electronic apparatus through the surface mount technology (SMT). It should be noted that the package technology of the electronic package structure 300 and the type of the leads 316 can be changed according to different design requirements, and the electronic package structure 300 is not limited to be the SMD. The electronic package structure 300 can also be a pin-through-hole device (PTH device). For example, the PTH device can be made through the DIP package (as shown in FIG. 3B(b)) technology or SIP package (as shown in FIG. 3B(c)) technology. Therefore, the first embodiment is used to illustrate, but not to limit the present invention in any aspects.

Furthermore, in the first embodiment, according to the relative position depicted in FIG. 3A, the first electronic elements 320 of the electronic package structure 300 are a logic control element, a capacitor, a resistor, and a power element including a MOSFET respectively from left to right. The first electronic elements 320 can all be dies, and the die is a structure that is directly cut from a wafer and is not packaged. The first electronic element 320 such as the logic control element and the first electronic element 320 such as the power element can be electrically connected to the first carrier 310 through a plurality of bonding wires 350. In other words, the first electronic element 320 such as the logic control element and the first electronic element 320 such as the power element can be electrically connected to the first carrier 310 through the wire bonding technology. Definitely, the first electronic element 320 such as the logic control element and the first electronic element 320 such as the power element can also be electrically connected to the first carrier 310 through a plurality of bumps (not shown). In other words, the first electronic element 320 such as the logic control element and the first electronic element 320 such as the power element can be electrically connected to the first carrier 310 through the flip-chip bonding technology, which is not shown.

In addition, the first electronic element 320 such as the capacitor and the first electronic element 320 such as the resistor can be electrically connected to the first carrier 310 through the solder paste (not shown). In other words, the first electronic element 320 such as the capacitor and the first electronic element 320 such as the resistor can be electrically connected to the first carrier 310 through the SMT. It should be noted that the method of connecting the first electronic elements 320 and the first carrier 310 can be changed according to different design requirements. Therefore, the first embodiment is used to illustrate, but not to limit the present invention in any aspects.

In addition, the second electronic element 330 can be a die, and electrically connected to the first carrier 310 through the wire bonding technology, SMT, or flip-chip bonding technology.

FIG. 3C is a schematic cross-sectional view of another electronic package structure according to the first embodiment of the present invention. Referring to FIG. 3C, the difference between the electronic package structure 300′ and the electronic package structure 300 is described as follows. The first electronic elements 320′ and the second electronic element 330′ of the electronic package structure 300′ can be all chip packages, and the chip package is a structure that is cut from a wafer and is packaged. For example, the first electronic elements 320′ and the second electronic element 330′ which are chip packages can be electrically connected to the first carrier 310′ through the solder paste (not shown) or conductive paste (not shown). In other words, the first electronic elements 320′ and the second electronic element 330′ which are chip packages can be electrically connected to the first carrier 310′ through the SMT. It should be emphasized that the second electronic element 330′ and at least one of the first electronic elements 320′ of the electronic package structure 300′ can also be designed as dies according to different design requirements. In other words, as a whole, the electronic package structure 300′ can include the electronic elements such as dies and the electronic elements such as chip packages, which is not shown in the drawings.

### The Second Embodiment

FIG. 4 is a schematic cross-sectional view of an electronic package structure according to a second embodiment of the present invention. Referring to FIG. 4, the difference between the electronic package structure 400 of the second embodiment and the electronic package structures 300 and 300′ of the first embodiment is described as follows. The electronic package structure 400 further includes a second carrier 460, and the number of the first electronic elements 420 is plural. A part of the first electronic elements 420 are disposed on the second carrier 460 and electrically connected to the second carrier 460. The second carrier 460 is disposed on a first carrying surface 412 of a first carrier 410, and electrically connected to the first carrier 410. In other words, in this embodiment, a part of the first electronic elements 420 are indirectly disposed on the first carrying surface 412, and the other part of the first electronic elements 420 (the most right first electronic element 420 in FIG. 4) are directly disposed on the first carrying surface 412. In addition, the second carrier 460 can be a wiring board.

The second carrier 460 such as the wiring board is composed of a plurality of wiring layers (not shown) and a plurality of dielectric layers (not shown) which are stacked alternately. At least two of the wiring layers are electrically connected to each other through at least one conductive via (not shown). Therefore, the layout density inside the second carrier 460 such as a wiring board is usually high, and the layout of the second carrier 460 such as a wiring board is often complicated. It should be noted that the appearance of the first carrier 410 and that of the second carrier 460 can be changed according to different design requirements. The second embodiment is used to illustrate, but not to limit the present invention in any aspects.

It should be noted that the electronic package structure 400 further includes an underfill 470 disposed between the second carrier 460 and one of the first electronic elements 420 (e.g., the leftest first electronic element 420 in FIG. 4). The underfill 470 is a non-conductive paste and filled between the second carrier 460 and the leftest first electronic element 420. When the leftest first electronic element 420 is disposed on the second carrier 460 through bumps 450, a clearance C is formed between the second carrier 460 and the leftest first electronic element 420, and an encapsulant 440 cannot fill the clearance C. The underfill 470 can be used to fill the clearance C, so as to prevent the heated bumps 450 from contacting one another to cause short circuit. In addition, the underfill 470 can bear part of stress, thereby reducing the stress on the bumps 450 such that the lifespan of the bumps 450 is extended.

### The Third Embodiment

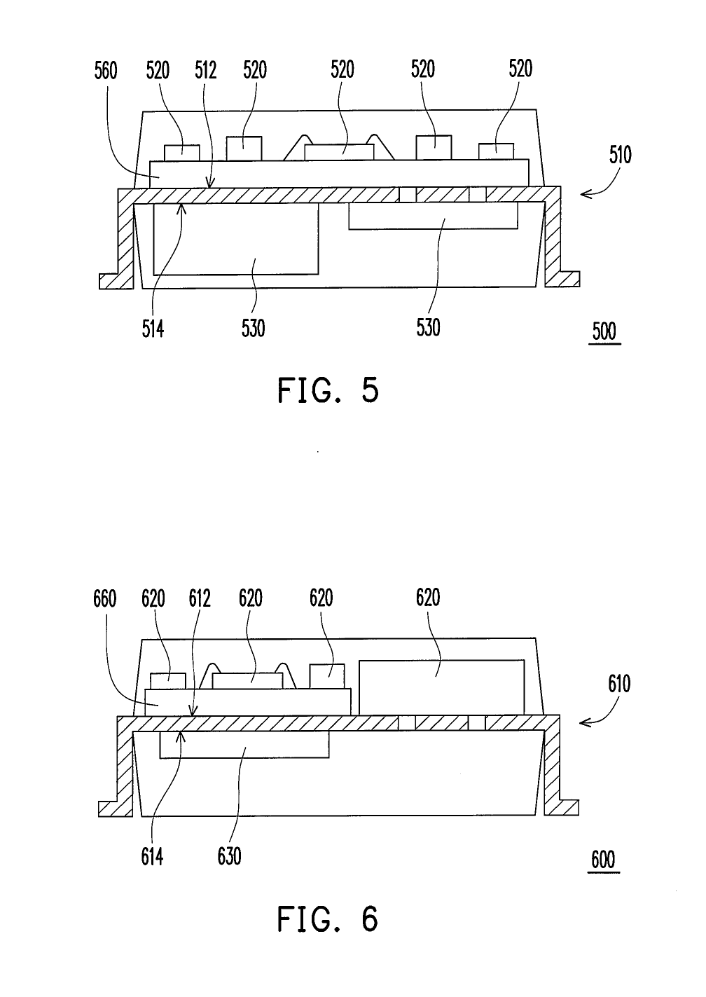

FIG. 5 is a schematic cross-sectional view of an electronic package structure according to a third embodiment of the present invention. Referring to FIG. 5, in the electronic package structure 500 according to the third embodiment, a second carrier 560 such as a wiring board is disposed on a first carrying surface 512 of a first carrier 510 such as a leadframe and electrically connected to the first carrier 510. The number of the first electronic element 520 is plural, and the first electronic elements 520 are indirectly disposed on the first carrying surface 512 through the second carrier 560. According to the relative position depicted in FIG. 5, the first electronic elements 520 disposed on the second carrier 560 are a resistor, a capacitor, a logic control element, a capacitor, and a resistor respectively from left to right. In addition, the number of the second electronic element 530 is plural, and the second electronic elements 530 disposed on a second carrying surface 514 of the first carrier 510 are an energy-storage element (e.g., a choke coil) and a power element (e.g., a MOSFET) respectively from left to right. Moreover, the first electronic elements 520 can be dies or chip packages and the second electronic elements 530 can be dies or chip packages. The electrical connection of the electronic elements is the same as that described in the first embodiment, and will not be described herein again.

### The Fourth Embodiment

FIG. 6 is a schematic cross-sectional view of an electronic package structure according to a fourth embodiment of the present invention. Referring to FIG. 6, in the electronic package structure 600 according to the fourth embodiment, a second carrier 660 such as a wiring board is disposed on a first carrying surface 612 of a first carrier 610 such as a leadframe and electrically connected to the first carrier 610. According to the relative position depicted in FIG. 6, the first electronic elements 620 disposed on the second carrier 660 are a resistor, a logic control element, and a capacitor respectively from left to right. In addition, the electronic package structure 600 further includes another first electronic element 620 disposed on the first carrying surface 612, and this first electronic element 620 can be an energy-storage element (e.g., a choke coil).

The second electronic element 630 disposed on a second carrying surface 614 of the first carrier 610 can be a power element (e.g., a MOSFET). The first electronic elements 620 can be dies or chip packages and the second electronic element 630 can be dies or chip packages. The electrical connection of the electronic elements is the same as that described in the first embodiment, and will not be described herein again.

### The Fifth Embodiment

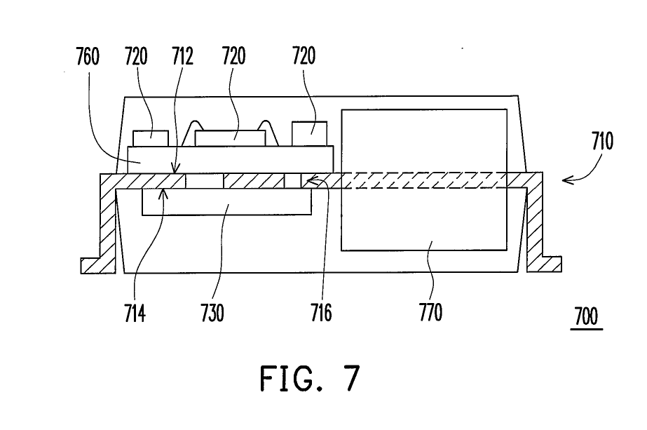

FIG. 7 is a schematic cross-sectional view of an electronic package structure according to a fifth embodiment of the present invention. Referring to FIG. 7, in the electronic package structure 700 according to the fifth embodiment, a second carrier 760 such as a wiring board is disposed on a first carrying surface 712 of a first carrier 710 such as a leadframe and electrically connected to the first carrier 710. According to the relative position depicted in FIG. 7, the first electronic elements 720 disposed on the second carrier 760 are a resistor, a logic control element, and a capacitor respectively from left to right. In addition, the second electronic element 730 disposed on a second carrying surface 714 of the first carrier 710 can be a power element (e.g., a MOSFET). The first electronic elements 720 and the second electronic element 730 can be dies or chip packages. The electrical connection of the electronic elements is the same as that described in the first embodiment, and will not be described herein again.

It should be noted that the electronic package structure 700 further includes at least one third electronic element 770 (one third electronic element 770 is schematically depicted in FIG. 7). The third electronic element 770 is disposed on a side surface 716 of the first carrier 710, and the side surface 716 connects the first carrying surface 712 and the second carrying surface 714. The third electronic element 770 can be an energy-storage element, e.g., a choke coil.

In the fourth, fifth, and sixth embodiments, the first electronic elements 520, 620, and 720 can also be directly disposed on the first carrying surface 512, 612, and 712, and the details can be known with reference to FIG. 3A and the related description, and will not be described herein again.

To sum up, the electronic package structure according to the present invention has at least the following advantages.

1. Since the second electronic element is disposed on the second carrying surface of the first carrier, and the first electronic element is disposed on the first carrying surface of the first carrier, the carrying space of the first carrier can be fully utilized. Therefore, the electronic elements in the electronic package structure of the present invention can be disposed in higher density.

2. The leadframe is used as the first carrier, so the heat of the first electronic element and the heat of the second electronic element disposed on the first carrier can be dissipated through fine heat dissipation paths provided by the leadframe. Therefore, the heat dissipation capacity of the electronic package structure is improved.

3. When the electronic package structure of the present invention is the SMD, the electronic package structure of the present invention can be electrically connected to the next-level electronic apparatus through the SMT. Therefore, the electronic package structure of the present invention can be assembled with the next-level electronic apparatus automatically such that the productivity is improved and the assembly cost is reduced.

4. Since the second electronic element is disposed on the second carrying surface of the first carrier, the first electronic element is disposed on the first carrying surface of the first carrier, and the third electronic element is disposed on the side surface of the first carrier, the carrying space of the first carrier can be fully utilized. Therefore, the electronic elements in the electronic package structure of the present invention can be disposed in higher density.

It will be apparent to persons of ordinary art in the art that various modifications and variations may be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An electronic package structure, comprising:
a first carrier, having a first carrying surface and a second carrying surface opposite to the first carrying surface;
at least one first electronic element, disposed on the first carrying surface and electrically connected to the first carrier;
at least one second electronic element, disposed on the second carrying surface and electrically connected to the first carrier; and
an encapsulant, at least covering the first electronic element, the second electronic element, and a part of the first carrier.

2. The electronic package structure as claimed in claim 1, wherein the volume of the second electronic element is larger than the volume of the first electronic element.

3. The electronic package structure as claimed in claim 1, comprises a plurality of the first electronic elements, wherein one of the first electronic elements is a control element, another one of the first electronic elements is a power element, and the second electronic element is an energy-storage element.

4. The electronic package structure as claimed in claim 1, comprises a plurality of the first electronic elements, wherein one of the first electronic elements is a control element, another one of the first electronic elements is an energy-storage element, and the second electronic element is a power element.

5. The electronic package structure as claimed in claim 1, comprises a plurality of the second electronic elements, wherein the first electronic element is a control element, one of the second electronic elements is an energy-storage element, and another one of the second electronic elements is a power element.

6. The electronic package structure as claimed in claim 1, further comprising at least one third electronic element disposed on a side surface of the first carrier, wherein the side surface connects the first carrying surface and the second carrying surface.

7. The electronic package structure as claimed in claim 6, wherein the third electronic element is an energy-storage element, the first electronic element is a control element, and the second electronic element is a power element.

8. The electronic package structure as claimed in claim 1, wherein the first carrier is a leadframe.

9. The electronic package structure as claimed in claim 1, further comprising a second carrier disposed on the first carrying surface and electrically connected to the first carrier, wherein the first electronic element is disposed on the second carrier and electrically connected to the second carrier.

10. The electronic package structure as claimed in claim 9, further comprising an underfill disposed between the second carrier and the first electronic element.

11. The electronic package structure as claimed in claim 9, comprises a plurality of the first electronic elements, a part of the first electronic elements are disposed on the second carrier and electrically connected to the second carrier, and the other part of the first electronic elements are disposed on the first carrying surface and electrically connected to the first carrier.

12. The electronic package structure as claimed in claim 9, wherein the second carrier is a wiring board.

13. The electronic package structure as claimed in claim 1, wherein the first electronic element is directly disposed on the first carrying surface, and the second electronic element is directly disposed on the second carrying surface.
